(19) United States
(12) Patent Application Publication
(10) Pub. No.: US 2025/0212565 A1
(43) Pub. Date: Jun. 26, 2025

(54) MOUNTING STRUCTURE AND SEMICONDUCTOR COMPONENT

(71) Applicant: Name NEC Corporation, Tokyo (JP)

(72) Inventor: Yoshiki TAMAMURA, Tokyo (JP)

(73) Assignee: Name NEC Corporation, Tokyo (JP)

(21) Appl. No.: 18/962,041

(22) Filed: Nov. 27, 2024

(30) Foreign Application Priority Data
Dec. 20, 2023 (JP) 2023-214572

(51) Int. Cl. H10H 20/85; H10H 20/857

(52) U.S. Cl. CPC H10H 20/8502; H10H 20/857

(57) ABSTRACT

Provided is a mounting structure and a semiconductor component that have a structure capable of suppressing creeping up of a bonding material. The mounting structure according to the present disclosure includes a carrier including a first surface having a first wettability with respect to a bonding material, and a conductor layer being provided on the first surface and having a second wettability higher than the first wettability with respect to the bonding material. The conductor layer includes a first region having at least four sides, and two or more second regions spaced apart from each other along a first side of the at least four sides.

### INCORPORATION BY REFERENCE

This application is based upon and claims the benefit of priority from Japanese patent application No. 2023-214572, filed on Dec. 20, 2023, the disclosure of which is incorporated herein in its entirety by reference.

### TECHNICAL FIELD

The present disclosure relates to a mounting structure and a semiconductor component, and more particularly, to a mounting structure and a semiconductor component for mounting an optical semiconductor element.

### BACKGROUND ART

Optical semiconductor elements such as a semiconductor optical amplifier (SOA) are being developed, and applications to not only a light-emitting component but also an in-vehicle device are expanding. Since the optical semiconductor elements generate heat along with light emission, high heat dissipation is required.

Japanese Unexamined Patent Application Publication No. 2019-161184 (Patent Literature 1) discloses a heat-generating component mounting body having a good heat dissipation property. The heat-generating component mounting body disclosed in Patent Literature 1 includes a substrate (carrier) having a heat-generating component including an electrode, a heat-radiating member, and a conductor provided opposite to the electrode, a bonding material (solder) for bonding the electrode and the conductor, and a bonding material regulating portion around the bonding material.

Meanwhile, in a semiconductor component in which an optical semiconductor element is mounted on a carrier via a bonding material such as solder, for example, the bonding material applied on the carrier may creep up to a side surface of the optical semiconductor element due to heat generation from the optical semiconductor element. Further, for example, if the optical semiconductor element is mounted on the carrier, the bonding material may creep up to the side surface of the optical semiconductor element. In a case where such creeping up occurs, a short circuit occurs between the carrier and the optical semiconductor element, and thus there is a concern that quality of the semiconductor component is deteriorated.

### SUMMARY

The present disclosure has been made in view of the above, and an example object of the present disclosure is to provide a mounting structure and a semiconductor component having a structure capable of suppressing creeping up of a bonding material.

In a first example aspect according to the present disclosure, a mounting structure includes a carrier including a first surface having a first wettability with respect to a bonding material, and a conductor layer being provided on the first surface and having a second wettability higher than the first wettability with respect to the bonding material, in which the conductor layer includes a first region having at least four sides, and two or more second regions being provided spaced apart from each other along a first side of the at least four sides.

In a second example aspect according to the present disclosure, a semiconductor component includes: a carrier including a first surface having a first wettability with respect to a bonding material; a conductor layer being provided on the first surface and having a second wettability higher than the first wettability with respect to the bonding material; and a semiconductor element being provided on the conductor layer via the bonding material, in which the conductor layer includes a first region having at least four sides, and two or more second regions being provided spaced apart from each other along a first side of the at least four sides, and the semiconductor element is in contact with a second side and a third side being adjacent to the first side and mounted on the first region.

### BRIEF DESCRIPTION OF DRAWINGS

The above and other aspects, features, and advantages of the present disclosure will become more apparent from the following description of certain example embodiments if taken in conjunction with the accompanying drawings, in which:

FIG. 1 is a diagram of a mounting structure according to the present disclosure;

FIG. 2 is a diagram of the mounting structure and a bonding material according to the present disclosure;

FIG. 3A is a diagram illustrating a conductor layer according to the present disclosure;

FIG. 3B is a diagram illustrating a conductor layer according to the present disclosure;

FIG. 3C is a diagram illustrating a conductor layer according to the present disclosure;

FIG. 3D is a diagram illustrating a conductor layer according to the present disclosure;

FIG. 4A is a diagram of a semiconductor component according to the present disclosure;

FIG. 4B is a diagram of a semiconductor component according to the present disclosure; and

FIG. 5A is a diagram illustrating creeping up of the bonding material; and

FIG. 5B is a diagram illustrating creeping up of the bonding material.

### EXAMPLE EMBODIMENT

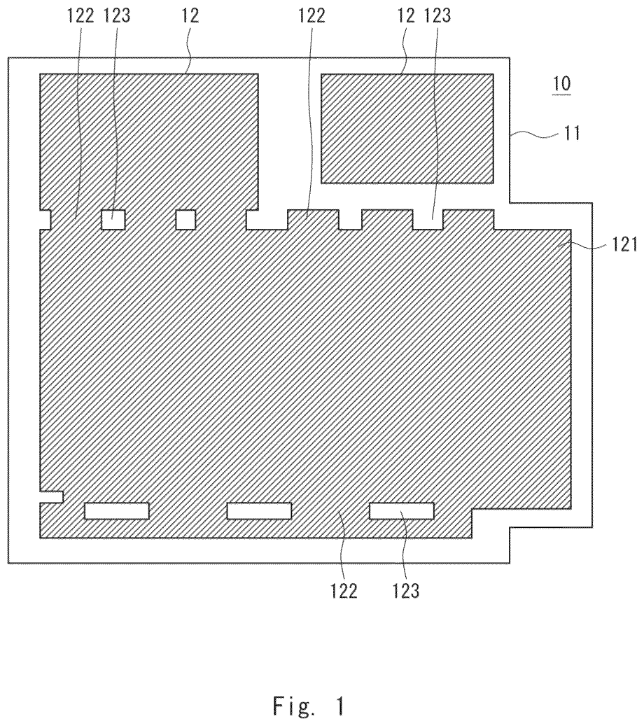

Hereinafter, a configuration example of a mounting structure 10 and a semiconductor component 100 according to the present disclosure is described with reference to the drawings. The mounting structure 10 illustrated in FIG. 1 includes a carrier 11 and a conductor layer 12 that is provided on a first surface of the carrier 11.

The carrier 11 is a substrate for mounting a semiconductor element, and is preferably constituted by a material having excellent heat dissipation. Examples of materials constituting the carrier 11 include aluminum nitride, silicon carbide, and silicon. The first surface of the carrier 11 has a first wettability with respect to a bonding material 20 to be described later.

The conductor layer 12 provided on the carrier 11 functions as an electrode electrically connected to the semiconductor element. The conductor layer 12 preferably includes a highly conductive material such as a metal. Examples of the highly conductive material include Au, Pt, Ag, Cu, Fe, Al, Ti, W and Ni, or alloys containing a plurality of types thereof. The surface of the conductor layer 12 has a second wettability higher than the first wettability with respect to the bonding material 20 to be described later. Therefore, since the bonding material 20 suitably spreads on the conductor layer 12, but hardly spreads on the first surface of the carrier 11, the first surface of the carrier 11 functions as a diffusion preventing layer of the bonding material 20.

The conductor layer 12 includes a first region 121 that is a region for providing the bonding material 20, and two or more second regions 122 that are provided spaced apart from each other along a predetermined side of the first region 121. Between the two or more second regions 122, there is a third region 123 where the surface of the carrier 11 is exposed. These areas are described in detail later.

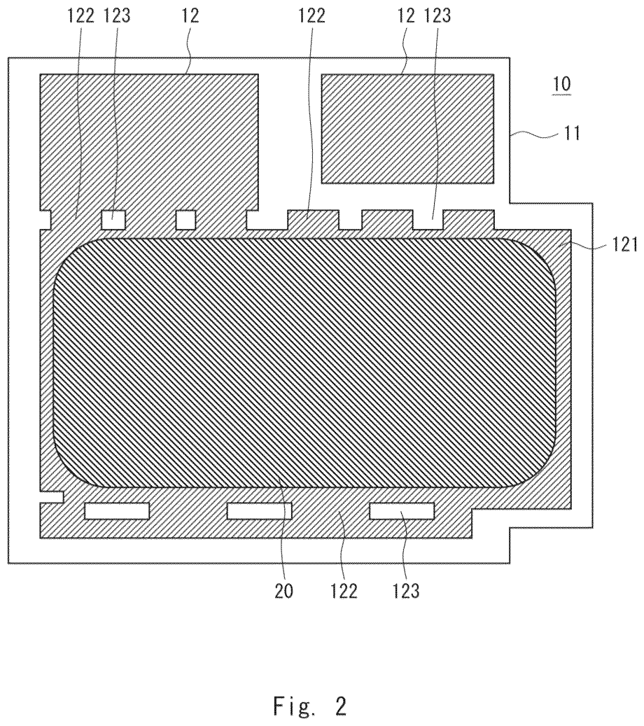

FIG. 2 illustrates a state in which the bonding material 20 is provided in the mounting structure 10. As the bonding material 20, it is preferable to use a solder containing a plurality of metal materials. The solder constituting the bonding material 20 is preferably an alloy of Sn (tin) and a metal material containing at least one selected from the group consisting of Au, Ag, Cu, Zn, In, Ga, Bi, Fe, Ti, Al, Sb and Ni. Further, the bonding material 20 is more preferably lead-free solder.

Further, the solder constituting the bonding material 20 preferably includes a metal included in the conductor layer 12. By selecting such a material, the conductor layer 12 is capable of having a high wettability with respect to the bonding material 20. For example, in a case where the conductive layer 12 containing Au and the bonding material 20 which is AuSn solder are used, the conductive layer 12 has a high wettability with respect to the bonding material 20, so that the bonding material 20 easily spreads on the conductive layer 12, which is preferable.

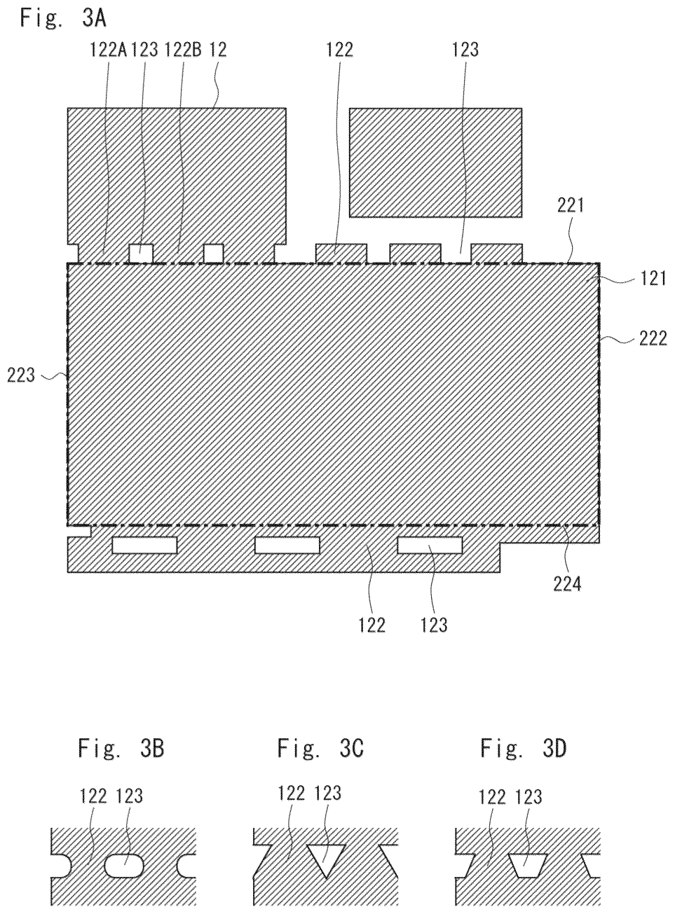

FIG. 3A is a top view of the conductor layer 12. A region surrounded by a dashed line in FIG. 3A indicates the above-described first region 121. The shape of the first region 121 is not particularly limited, but is preferably a polygonal shape or a rounded polygonal shape having at least four sides. The first region 121 illustrated in FIG. 3A has a first side 221, a second side 222 and a third side 223 adjacent to the first side 221, and a fourth side 224 opposed to the first side 221.

Preferably, two or more second regions 122 are provided along the first side 221 of the first region 121 so as to be spaced apart from each other. Between the two second regions 122A and 122B illustrated in FIG. 3A, there is a third region 123 where the first surface of the carrier 11 is exposed. The third region 123 may be used as a mounting marker in a step of mounting a semiconductor element on the bonding material 20.

Further, the shapes of the second region 122 and the third region 123 are not limited to the rectangular shapes illustrated in FIG. 3A. Examples of the shapes of the second region 122 and the third region 123 are illustrated in FIGS. 3B to 3D. The shape of the second region 122 is preferably determined such that the shape of the third region 123 is any one of a circular shape, an elliptical shape, a triangular shape, a trapezoidal shape, and a polygonal shape of a pentagon or more. In particular, in the case where the third region 123 is used as a mounting marker, it is preferable that any one of a triangular shape, a trapezoidal shape, and a polygonal shape having a pentagonal shape or more is used because alignment adjustment at the time of mounting is easy.

As will be described later, the second region 122 is a region into which excess bonding material 20 flows. Therefore, as illustrated in FIGS. 3C and 3D, in the shape of the second region 122, it is preferable that the longest side is in contact with the first side 221. In this way, the bonding material 20 can easily flow into the second region 122 while maintaining the visibility of the mounting marker.

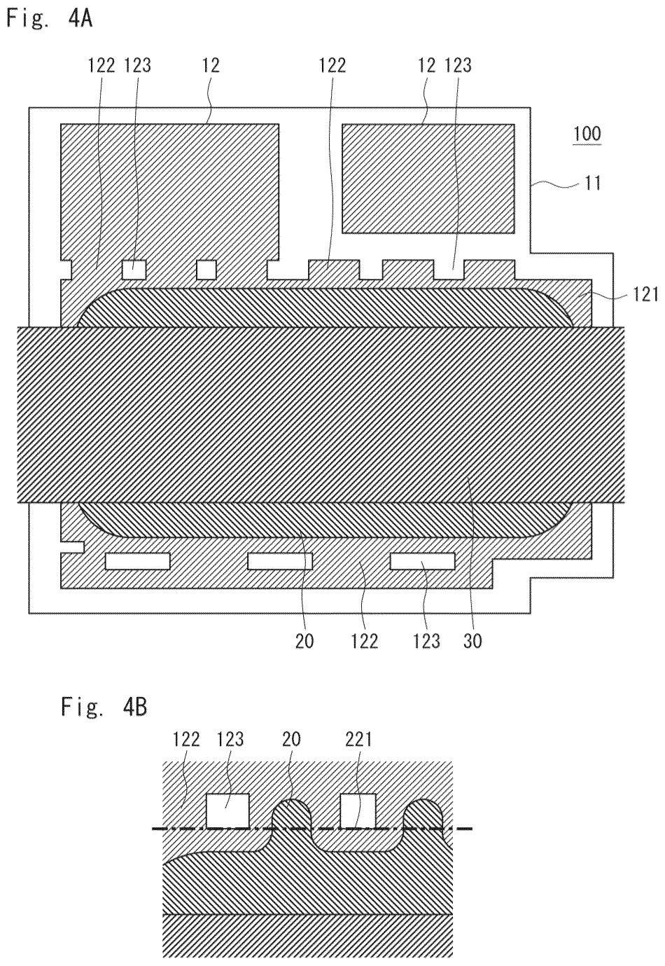

FIG. 4A illustrates a configuration example of a semiconductor component 100 according to the present disclosure. The semiconductor component 100 includes a semiconductor element 30 provided on a conductor layer 12 via a bonding material 20. The semiconductor element 30 is preferably mounted so as to be in contact with a second side 222 and a third side 223 of a first region 121 of the conductor layer 12. With this configuration, the bonding material 20 is less likely to spread toward the second side 222 and the third side 223, and is more likely to spread toward a first side 221 and a fourth side 224.

As the semiconductor element 30, a semiconductor optical amplifier (SOA), a light-emitting diode (LED) element, a laser diode (LD) element, or the like is used.

FIG. 4B illustrates a state in which the bonding material 20 extends beyond the first side 221 of the first region 121 until the bonding material 20 overlaps with a part of the second region 122. As described above, by providing a region in which the bonding material 20 is wetted and spread, it is possible to prevent the bonding material 20 from creeping up to the side surface of the semiconductor element 30. Although not illustrated in the drawings, the bonding material 20 may also spread on the fourth side 224 until the bonding material 20 overlaps with a part of the second region 122.

Further, the third region 123 in which the first surface of the carrier 11 is exposed has a characteristic that the bonding material 20 hardly flows into the third region 123 because the wettability with respect to the bonding material 20 is lower than that of the conductor layer 12. Therefore, even in a case where the third region 123 is used as a mounting marker of the semiconductor element 30, since the bonding material 20 does not flow onto the mounting marker, it is possible to maintain the visibility of the mounting marker.

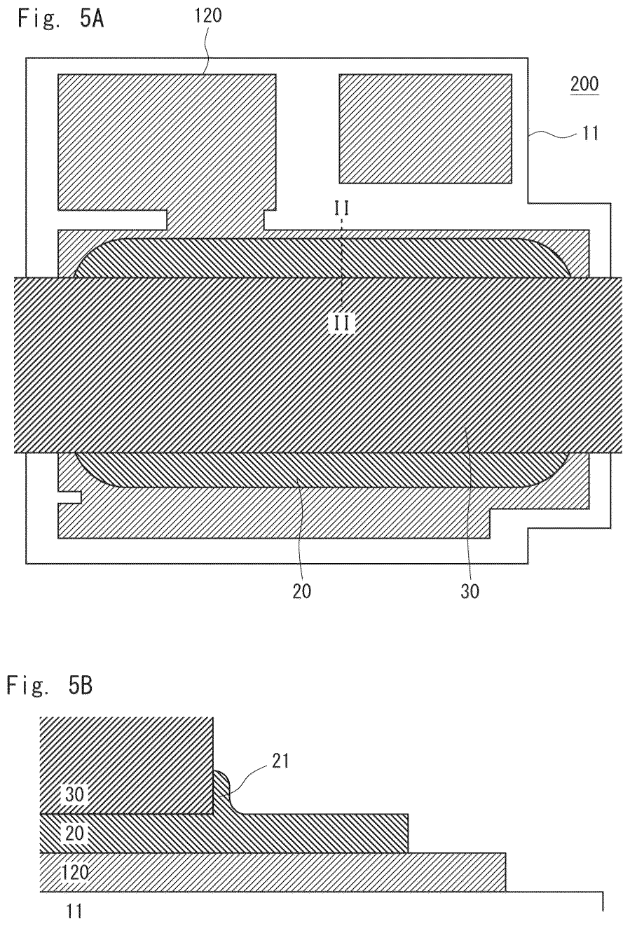

Here, the creeping up of the bonding material 20 is described with reference to FIG. 5. FIG. 5A illustrates a configuration example of the semiconductor component 200 in a case where the semiconductor element 30 is provided on the conductor layer 120 not provided with the second region 122 via the bonding material 20. FIG. 5B is a cross-sectional view taken along a broken line II-II in FIG. 5A. A region 21 in which the bonding material 20 creeps up to the side surface of the semiconductor element 30 is generated due to the influence of heat generation of the semiconductor element 30, variation in the thickness of the bonding material 20, and the like. In a case where such a creeping-up region 21 is generated, short circuit may occur between the carrier 11 and the semiconductor element 30, which is not preferable.

Meanwhile, in the mounting structure 10 and the semiconductor component 100 according to the present disclosure, since the second region 122 is provided, it is possible to prevent the excess bonding material 20 from flowing into the second region 122 and the bonding material 20 from creeping up to the semiconductor element 30.

Although the present disclosure has been described with reference to the example embodiments, the present disclosure is not limited to the above-described example embodiments. Various changes that can be understood by a person skilled in the art within the scope of the present disclosure can be made to the configuration and details of the present disclosure.

The drawings are merely illustrative of one or more example embodiments. Each drawing may be associated with one or more other example embodiments, rather than only one particular example embodiment. As those skilled in the art will appreciate, various features or steps described with reference to any one of the figures may be combined with features or steps illustrated in one or more other figures, for example, to create example embodiments not explicitly illustrated or described. All of the features or steps illustrated in any one of the figures to describe the exemplary example embodiments are not necessarily essential, and some features or steps may be omitted. The order of the steps described in any of the figures may be changed as appropriate.

The whole or part of the exemplary example embodiments disclosed above can be described as, but not limited to, the following Supplementary notes.

### (Supplementary Note 1)

A mounting structure including:
a carrier including a first surface having a first wettability with respect to a bonding material; and
a conductor layer being provided on the first surface and having a second wettability higher than the first wettability with respect to the bonding material, in which the conductor layer includes a first region having at least four sides, and two or more second regions being provided spaced apart from each other along a first side of the at least four sides.

### (Supplementary Note 2)

The mounting structure according to Supplementary note 1, in which a shape of the two or more second regions is determined in such a way that a region where the carrier is exposed between the two or more second regions is any one of a circular shape, an elliptical shape, a triangular shape, a trapezoidal shape, and a pentagonal or more polygonal shape.

### (Supplementary Note 3)

The mounting structure according to Supplementary note 2, in which the region where the first surface of the carrier is exposed functions as a mounting marker of a semiconductor element.

### (Supplementary Note 4)

The mounting structure according to any one of claims 1 to 3, in which the first region has a polygonal shape or a rounded polygonal shape including the first side, a second side and a third side being adjacent to the first side, and a fourth side opposed to the first side.

### (Supplementary Note 5)

A semiconductor component including:
a carrier including a first surface having a first wettability with respect to a bonding material,
a conductor layer being provided on the first surface and having a second wettability higher than the first wettability with respect to the bonding material, and
a semiconductor element being provided on the conductor layer via the bonding material, in which
the conductor layer includes a first region having at least four sides, and two or more second regions being provided spaced apart from each other along a first side of the at least four sides, and
the semiconductor element is in contact with a second side and a third side being adjacent to the first side and mounted on the first region.

### (Supplementary Note 6)

The semiconductor component according to Supplementary note 5, in which a shape of the two or more second regions is determined in such a way that a region where the carrier is exposed between the two or more second regions is any one of a circular shape, an elliptical shape, a triangular shape, a trapezoidal shape, and a pentagonal or more polygonal shape.

### (Supplementary Note 7)

The semiconductor component according to Supplementary note 6, in which the region in which the first surface of the carrier is exposed functions as a mounting marker of the semiconductor element.

### (Supplementary Note 8)

The semiconductor component according to any one of Supplementary notes 5 to 7, in which the first region is a polygonal shape or a rounded polygonal shape including the first side, the second side, the third side, and a fourth side opposed to the first side.

### (Supplementary Note 9)

The semiconductor component according to any one of Supplementary notes 5 to 7, in which the bonding material is a solder layer containing a metal material contained in the conductor layer.

### (Supplementary Note 10)

The semiconductor component according to any one of Supplementary notes 5 to 7, in which the bonding material has a region overlapping with a part of the two or more second regions.

Some or all of the elements (e.g., configurations and functions) described in Supplementary notes 2 to 4 depending on the mounting structure described in Supplementary note 1 may also be dependent on the semiconductor component described in Supplementary note 5 by similar dependencies. Some or all of the elements described in any Supplementary note may be applied to various hardware, software, recording means, systems, and methods for recording software.

According to the present disclosure, it is possible to provide a mounting structure and a semiconductor component having a structure capable of suppressing creeping up of a bonding material.

While the disclosure has been particularly shown and described with reference to example embodiments thereof, the disclosure is not limited to these example embodiments. It will be understood by those of ordinary skill in the art that various changes in form and details may be made therein without departing from the spirit and scope of the present disclosure as defined by the claims.

What is claimed is:

1. A mounting structure comprising:
a carrier including a first surface having a first wettability with respect to a bonding material; and
a conductor layer being provided on the first surface and having a second wettability higher than the first wettability with respect to the bonding material,
wherein the conductor layer includes a first region having at least four sides, and two or more second regions being provided spaced apart from each other along a first side of the at least four sides.

2. The mounting structure according to claim 1, wherein a shape of the two or more second regions is determined in such a way that a region where the carrier is exposed between the two or more second regions is any one of a circular shape, an elliptical shape, a triangular shape, a trapezoidal shape, and a polygonal shape of a pentagon or more.

3. The mounting structure according to claim 2, wherein the region where the first surface of the carrier is exposed functions as a mounting marker of a semiconductor element.

4. The mounting structure according to claim 1, wherein the first region has a polygonal shape or a rounded polygonal shape including the first side, a second side and a third side being adjacent to the first side, and a fourth side opposed to the first side.

5. A semiconductor component comprising:
a carrier including a first surface having a first wettability with respect to a bonding material,
a conductor layer being provided on the first surface and having a second wettability higher than the first wettability with respect to the bonding material, and
a semiconductor element being provided on the conductor layer via the bonding material, wherein
the conductor layer includes a first region having at least four sides, and two or more second regions being provided spaced apart from each other along a first side of the at least four sides, and
the semiconductor element is in contact with a second side and a third side being adjacent to the first side and mounted on the first region.

6. The semiconductor component according to claim 5, wherein a shape of the two or more second regions is determined in such a way that a region where the carrier is exposed between the two or more second regions is any one of a circular shape, an elliptical shape, a triangular shape, a trapezoidal shape, and a polygonal shape of a pentagon or more.

7. The semiconductor component according to claim 6, wherein the region where the first surface of the carrier is exposed functions as a mounting marker of the semiconductor element.

8. The semiconductor component according to claim 5, wherein the first region has a polygonal shape or a rounded polygonal shape including the first side, the second side, the third side, and a fourth side opposed to the first side.

9. The semiconductor component according to claim 5, wherein the bonding material is a solder layer containing a metal material contained in the conductor layer.

10. The semiconductor component according to claim 5, wherein the bonding material has a region overlapping a part of the two or more second regions.
